(19) United States
(12) Patent Application Publication
(10) Pub. No.: US 2010/0283145 A1
(43) Pub. Date: Nov. 11, 2010

(54) Stack structure with copper bumps

(76) Inventors: Chien-Wei Chang, Taoyuan (TW); Ting-Hao Lin, Taipei (TW); Yu-Te Lu, Taoyuan (TW); Wen-Chun Huang, Taoyuan (TW)

Correspondence Address: LIN & ASSOCIATES INTELLECTUAL PROPERTY, INC., P.O. BOX 2339, SARATOGA, CA, 95070-0339, US

(21) Appl. No.: 12/435,409

(22) Filed: May 5, 2009

(51) Int. Cl. H01L 23/498

(52) U.S. Cl. 257/737; 257/E23.072

(57) ABSTRACT

A stack structure with copper bumps on an integrated circuit board is disclosed. The stack structure includes a plurality of insulating layers and a plurality of conductive layers which are stacked alternately. The uppermost conductive layer has copper bumps as copper pillar pins for soldering the chip pins of an integrated circuit chip. Because the copper bumps have a certain height, the distance between the copper bumps and the chip pins is shortened, and therefore the solders needed for soldering may be reduced. Also, the shape of the solders is a long strap instead of spheroid due to the cohesion force between the copper bump surfaces and the solders so that the distance between the solders is scaled down and the gaps between the pins are reduced. Thus, the entire size of the integrated circuit board may also be miniatured.

### BACKGROUND OF THE INVENTION

1. Field of the Invention

The present invention relates to a stack structure with copper bumps, and more particularly, to a circuit board which has copper bumps as copper pillar pins on the uppermost layer.

2. The Prior Arts

In the IC assembly process of wafer solder bumping, solder bumps are first fabricated on an aluminum pad of a wafer by using films, photolithography, and electroplating processes or printing technique. In the later process of IC assembly, the bumps are melted by heat, and then soldered with the aluminum pads on a circuit board. This technique may substantially reduce IC size together with the advantages, such as high density, low sensitivity, low cost, and excellent heat dissipation.

Please refer to FIG. 1. FIG. 1 is a schematic diagram illustrating a conventional connection between an integrated circuit and a circuit board by a solder bumping technique. The integrated circuit board 1 includes a chip layer 10 and a circuit board 20. The chip layer 10 has a plurality of chip pins 12 thereon, which are connected to the board pins 22 on the circuit board 20 by the solders 30. The fabrication limit of the bump gap d1 between the chip pin 12 and the board pin 22 is about 150-180 μm.

Please refer to FIG. 2. FIG. 2 is a schematic diagram illustrating another conventional connection between an integrated circuit and a circuit board by solder bumping technique. The chip pins 12 and the board pins 22 are arranged much denser, and thus the bump gap d2 is greatly reduced. When the chip layer 10 and circuit board 20 are connected by the solders 30, there may be a risk of short circuit between the solders 30.

### SUMMARY OF THE INVENTION

The main object of the present invention is to provide a stack structure with copper bumps, which includes a plurality of conductive copper layers, a plurality of insulating layers and a plurality of copper bumps, wherein the plurality of conductive copper layers and the plurality of insulating layers are stacked alternately. The uppermost layer is the first conductive copper layer, on which the plurality of copper bumps are formed to solder the chip pins of an integrated circuit chip. The shape of the solders is a long strap instead of spheroid by the cohesion force between the copper bump surfaces and the solders, and the distance between the solders is reduced so that the gap between the chip pins and the gap between the copper bumps are reduced. Therefore, the entire integrated circuit structure may also be reduced or more chip pins may be layouted in the same area.

Comparing with the prior arts, the present invention employs the characteristics of the copper bumps and the solders with a certain height on the first conductive copper layer to obtain a denser arrangement of chip pins; and therefore the risk of short circuit between the solders at the time of soldering may be reduced.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a schematic diagram illustrating a conventional connection between an integrated circuit and a circuit board by solder bumping technique;

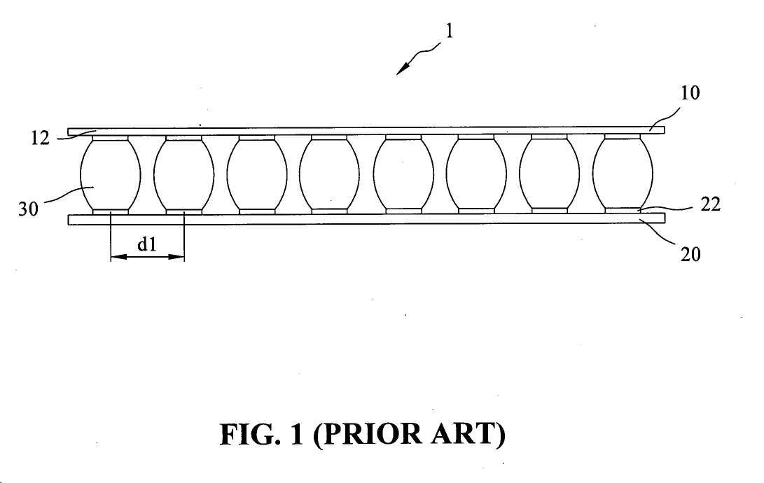

FIG. 2 is a schematic diagram illustrating another conventional connection between an integrated circuit and a circuit board by solder bumping technique;

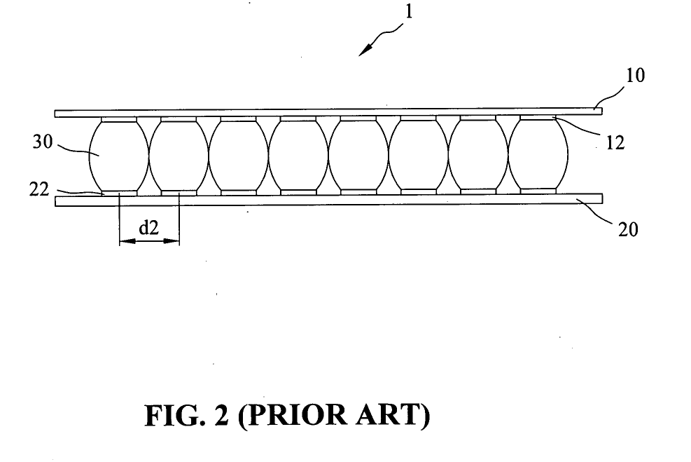

FIG. 3 is a schematic diagram of a stack structure according to a first embodiment of the present invention;

FIG. 4 is a schematic diagram of a stack structure according to a second embodiment of the present invention; and

FIG. 5 is a schematic diagram illustrating the soldering between the stack structure with copper bumps and chip pins according to the present invention.

### DETAILED DESCRIPTION OF THE PREFERRED EMBODIMENT

Reference will now be made in detail to an embodiment of the present invention, examples of which are illustrated in the accompanying drawings.

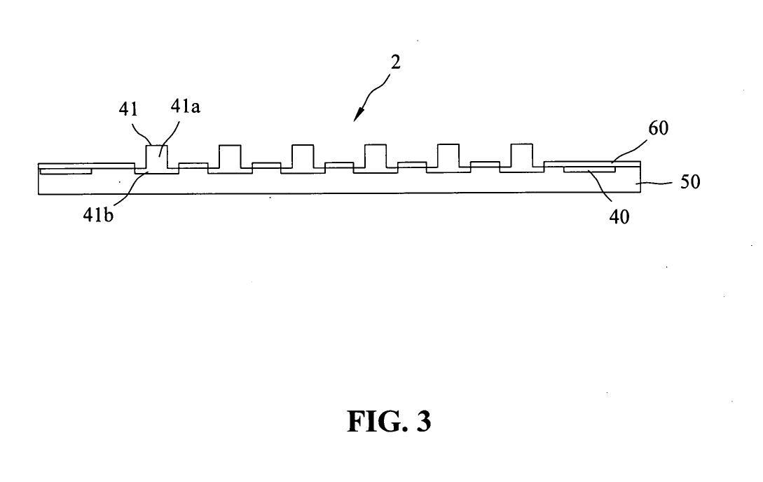

Please refer to FIG. 3. FIG. 3 is a schematic diagram of a stack structure according to a first embodiment of the present invention. In accordance with this embodiment, a stack structure 2 with copper bumps includes a first conductive copper layer 40, a plurality of copper bumps 41, a first insulating layer 50, and a first solder mask 60. The first conductive copper layer 40 has a circuit pattern (not shown) which covers a portion of the upper layer of the first insulating layer 40. The circuit pattern has a plurality of copper bumps 41. Each of these copper bumps 41 has a bumpy portion 41a and a bottom portion 41b. The bumpy portion 41a is located on the bottom portion 41b. The bumpy portion 41a has a width and a height and the bottom portion 41b has a width and a height. The width of the bumpy portion 41a is smaller than that of the bottom portion 41b. The first solder mask 60 covers the portions of the upper surface of the first insulating layer 50 which are not covered by the circuit pattern and the portions of the circuit pattern which are not covered by the copper bumps 41.

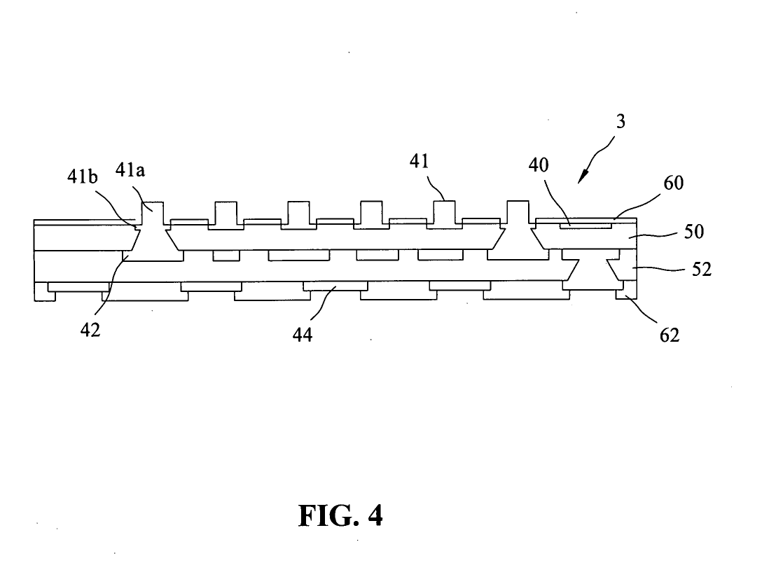

Please refer to FIG. 4. FIG. 4 is a schematic diagram of a stack structure according to a second embodiment of the present invention. In accordance with this embodiment, a stack structure 3 with copper bumps includes a first conductive copper layer 40, a plurality of copper bumps 41, a second conductive copper layer 42, a third conductive copper layer 44, a first insulating layer 50, a second insulating layer 52, a first solder mask 60, and a second solder mask 62. The first conductive copper layer 40 has a circuit pattern (not shown) which covers a portion of the upper layer of the first insulating layer 40. The circuit pattern has a plurality of copper bumps 41. Each of these copper bumps 41 has a bottom portion 41b and a bumpy portion 41a. The bumpy portion 41a is located on the bottom portion 41b. The bumpy portion 41a has a width and a height and the bottom portion 41b has a width and a height. The width of the bumpy portion 41a is smaller than the width of the bottom portion 41b. The first solder mask 60 covers the portions of the upper surface of the first insulating layer 50 which are not covered by the circuit pattern and the portions of the circuit pattern which are not covered by the copper bumps 41. The second conductive copper layer 42 has a circuit pattern which is located between a portion of the bottom surface of the first insulating layer 50 and a portion of the upper surface of the second insulating layer 52. The third conductive copper layer 44 has a circuit pattern which is located at a portion of the second insulating layer 52. The second solder mask covers the bottom surface of the second insulating layer 52.

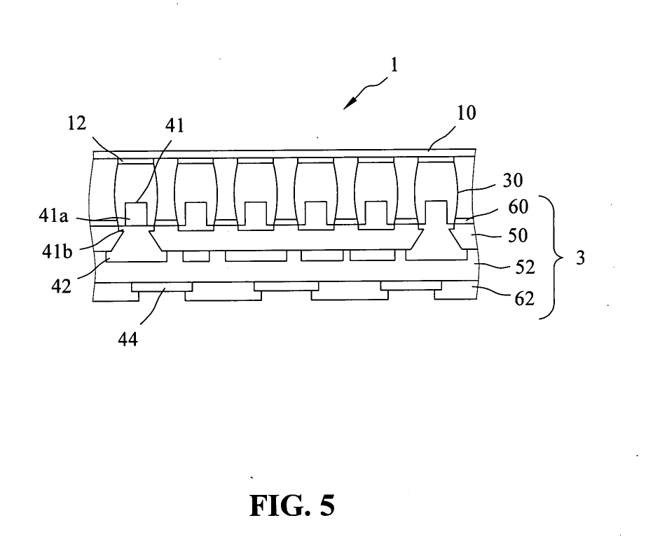

Please refer to FIG. 5. FIG. 5 is a schematic diagram illustrating the soldering between the stack structure with copper bumps and chip pins according to the present invention. In this diagram, the copper bumps 41 of the stack structure 3 with copper bumps and the chip pins 12 on the chip layer 10 are connected by soldering. The bumpy portions 41a of the copper bumps 41 have a certain height so that the distance to the chip pins 12 is shortened and the solders 30 needed for soldering may be reduced. Also, the shape of the solders 30 is a long strap instead of spheroid due to the cohesion force between the copper bumps 41 and the solders 30, and thus the distance between the solders 30 are scaled-down. Then the gaps between the chip pins 12 and the gaps between the copper bumps 41 are reduced under the general fabrication limit, such as 150-180 μm. Therefore, the entire size of the integrated circuit board 1 may be miniatured.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A stack structure with copper bumps, comprising:
a first insulating layer with an upper surface and a bottom surface;
a first conductive copper layer with a circuit pattern which covers a portion of the upper surface of the first insulating layer and has a plurality of copper bumps; and
a first solder mask which covers the portions of the upper surface of the first insulating layer which are not covered by the circuit pattern and the portions of the circuit pattern which are not covered by the copper bumps.

2. The stack structure with copper bumps of claim 1, wherein each of the copper bumps has a bumpy portion and a bottom portion, the bumpy portion has a width and a height, the bottom portion has a width and a height, and the width of the bumpy portion is smaller than that of the bottom portion.

3. A stack structure with copper bumps, comprising:
a first insulating layer with an upper surface and a bottom surface;
a first conductive copper layer with a circuit pattern which covers a portion of the upper surface of the first insulating layer and has a plurality of copper bumps;
a first solder mask which covers the portions of the upper surface of the first insulating layer which are not covered by the circuit pattern and the portions of the circuit pattern which are not covered by the copper bumps;
a second insulating layer with an upper surface and a bottom surface;
a second conductive copper layer with a circuit pattern which is located between a portion of the bottom surface of the first insulating layer and a portion of the upper surface of the second insulating layer;
a third conductive copper layer with a circuit pattern which is located at a portion of the second insulating layer; and
a second solder mask which covers the bottom surface of the second insulating layer.

4. The stack structure with copper bumps of claim 3, wherein each of the copper bumps has a bumpy portion and a bottom portion, the bumpy portion has a width and a height, the bottom portion has a width and a height, and the width of the bumpy portion is smaller than that of the bottom portion.
